(19) United States
(12) Patent Application Publication
(10) Pub. No.: US 2026/0333910 A1
(43) Pub. Date: Oct. 22, 2026

(54) OPTICAL DEVICE WITH LEAK-PROOF STRUCTURE

(71) Applicant: PixArt Imaging Inc., Hsin-Chu City (TW)

(72) Inventors: Hung-Yu Lai, Hsin-Chu City (TW); Yen-Hung Wang, Hsin-Chu City (TW); Yueh-Ling Hsu, Hsin-Chu City (TW)

(73) Assignee: PixArt Imaging Inc., Hsin-Chu City (TW)

(21) Appl. No.: 19/182,534

(22) Filed: Apr. 17, 2025

(51) Int. Cl. H10F 39/00; G02B 27/00; H01L 25/16

(52) U.S. Cl. CPC H10F 39/804; H10F 39/806; H10F 39/8063; H10W 90/00; G02B 27/0006

(57) ABSTRACT

An optical device, comprising: a light blocking structure; a first optical component, located in a first region next to the light blocking structure; and a first lens device, located in the first region and above the first optical component. A touch region of the first lens device and the light blocking structure forms a first touch surface, wherein the first touch surface comprises at least one first bending portion.

### BACKGROUND OF THE INVENTION

### 1. Field of the Invention

The present invention relates to an optical device, and particularly relates to an optical device which can prevent liquid leaks.

### 2. Decription of the Prior Art

In the prior art, optical devices may comprise light blocking structure to block certain optical components from receiving unnecessary light. However, gaps may exist between the light blocking structure and other components, resulting in water leakage. Therefore, an optical device having a water leakage proof structure is required.

### SUMMARY OF THE INVENTION

One objective of the present invention is to provide an optical device with a water proof structure.

One embodiment of the present invention discloses an optical device, comprising: a light blocking structure; a first optical component, located in a first region next to the light blocking structure; and a first lens device, located in the first region and above the first optical component. A touch region of the first lens device and the light blocking structure forms a first touch surface, wherein the first touch surface comprises at least one first bending portion.

In one embodiment, the light blocking structure comprises a concave portion and the first lens device comprises a protruding portion, wherein the first bending portion is formed by the protruding portion bedding into the concave portion. Alternatively, in one embodiment, the light blocking structure comprises a protruding portion and the first lens device comprises a concave portion, wherein the first bending portion is formed by the protruding portion bedding into the concave portion.

In one embodiment, the optical device further comprises: a second optical component, located in a second region next to the light blocking structure; and a second lens device, located in the second region and above the second optical component. A touch region of the second lens device and the light blocking structure forms a second touch surface, wherein the second touch surface comprises at least one second bending portion.

In one embodiment, the light blocking structure comprises a concave portion and the second lens device comprises a protruding portion, wherein the second bending portion is formed by the protruding portion bedding into the concave portion. Alternatively, the light blocking structure comprises a protruding portion and the second lens device comprises a concave portion, wherein the second bending portion is formed by the protruding portion bedding into the concave portion.

One embodiment of the present invention discloses an optical device, comprising: a light blocking structure; a first optical component, located in a first region next to the light blocking structure; and a first lens device, located in the first region and above the first optical component; a second optical component, located in a second region next to the light blocking structure; and a second lens device, located in the second region and above the second optical component. The first lens device and the second lens device form a sharing portion above the light blocking structure. The sharing portion has diffusing structure configured to diffuse light.

In one embodiment, the second optical component is a light source; wherein the diffusing structure is configured to diffuse the light emitted from the first optical component. In another embodiment, the first optical component is an image sensor, and the light blocking structure is configured to prevent the first optical component from receiving light from the second optical component.

In one embodiment, the first optical component is a light source and the second optical component is an image sensor.

In view of above-mentioned embodiments, the water proof function of the optical device can be improved by simple structures, thus the water leakage issue can be improved without increasing much cost and the assembly complexity.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an optical device according to one embodiment of the present invention.

FIG. 2 is a schematic diagram illustrating an enlarge drawing of a portion of the embodiment illustrated in FIG. 1.

FIG. 3 is a schematic diagram illustrating an optical device according to another embodiment of the present invention.

FIG. 4 is a schematic diagram illustrating an enlarge drawing of a portion of the embodiment illustrated in FIG. 3.

FIG. 5 is a schematic diagram illustrating an optical device according to still another embodiment of the present invention.

FIG. 6 is a schematic diagram illustrating an enlarge drawing of the sharing portion of the embodiment illustrated in FIG. 5.

FIG. 7 is a schematic diagram illustrating an optical device according to another embodiment of the present invention.

### DETAILED DESCRIPTION

In the following descriptions, several embodiments are provided to explain the concept of the present application. The term “first”, “second”, “third” in following descriptions are only for the purpose of distinguishing different one elements, and do not mean the sequence of the elements. For example, a first device and a second device only mean these devices can have the same structure but are different devices. Please note, the water leakage proof structure stated below may also be used to prevent leakages of other liquid.

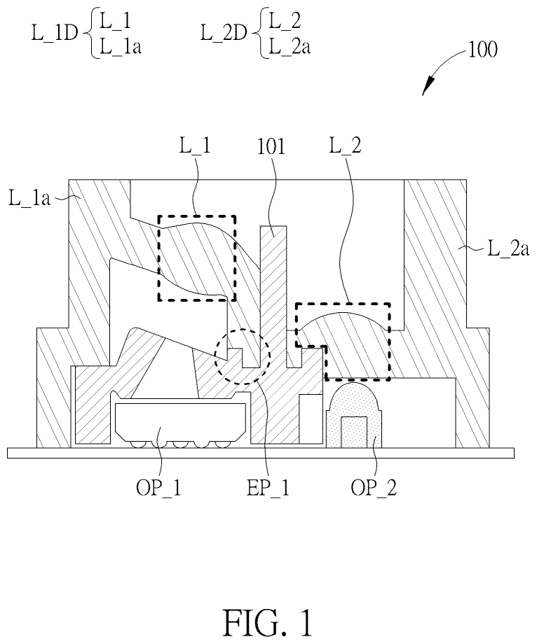

FIG. 1 is a schematic diagram illustrating an optical device according to one embodiment of the present invention. As shown in FIG. 1, the optical device 100 comprises a light blocking structure 101, a first optical component OP_1, a first lens device L_1D, a second optical component OP_2, and a second lens device L_2D. The first lens device L_1D may comprise the first lens itself (i.e., the first lens L_1) and a first auxiliary optical component L_1a which is connected to the first lens L_1 or formed integrally with the first lens L_1. Similarly, the second lens device L_2D may comprise the second lens itself (i.e., the second lens L_2) and a second auxiliary optical component L_2a which is connected to the second lens L_2 or formed integrally with the second lens L_2. For more detail, in one embodiment, the light emitted to the first optical component OP_1 passes through the first lens L_1 but does not pass through the first auxiliary optical component L_1a. Also, the light emitted from the second optical component OP_2 passes through the second lens L_2 but does not pass through the second auxiliary optical component L_2a.

The first optical component OP_1 is located in a first region next to the light blocking structure 101. The first lens L_1 is located in the first region and above the first optical component OP_1. In this embodiment and following embodiments, the first optical component OP_1 is an image sensor and the second optical component OP_2 is a light source. Accordingly, the optical device 100 can be provided in a camera or an optical navigation device such as an optical mouse, or any device which needs to sense images. However, the optical device of the present invention can comprise only one optical component rather than limited to more than one optical components.

In such case, the light blocking structure 101 is configured to prevent the first optical component OP_1 from receiving light from the second optical component OP_2. However, the first optical component OP_1 and the second optical component OP_2 are not limited to the above-mentioned examples.

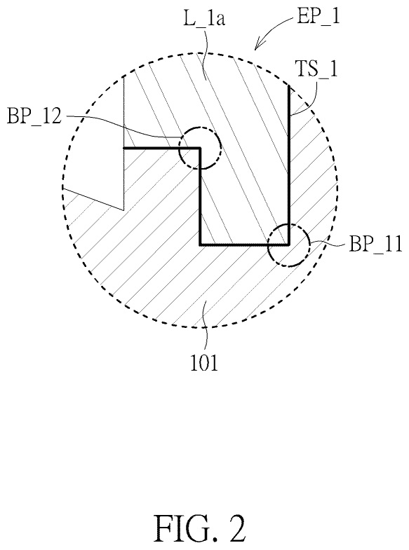

Please refer to FIG. 2, which is a schematic diagram illustrating an enlarge drawing of a portion EP_1 of the embodiment illustrated in FIG. 1. As shown in FIG. 2, a touch region, in which the first auxiliary optical component L_1a and the light blocking structure 101 touches each other, forms a first touch surface TS_1. The first touch surface TS_1 comprises at least one first bending portion, such as the first bending portions BP_11 and BP_12 in FIG. 2. Please note, in this embodiment and following embodiments, there are still other bending portions, but only some of them are using as examples for explaining. In one embodiment, the bending portion represents the curvature change of the surface thereof is greater than a predetermined angle (e.g., 60° or 90°).

For more detail, in FIG. 2, the light blocking structure 101 comprises a concave portion and the first auxiliary optical component L_1a comprises a protruding portion. In such case, the first bending portion BP_11 is formed by the protruding portion bedding into the concave portion. Also, in FIG. 2, the light blocking structure 101 comprises a protruding portion and the first auxiliary optical component L_1a comprises a concave portion, wherein the first bending portion BP_12 is formed by the protruding portion bedding into the concave portion.

In the embodiment of FIG. 2, since the bending portion BP_11 and BP_12 prolong the path through which water flows, a stronger water leakage prevention function can be provided when water penetrates into the optical device 100. In one embodiment, water proof material may be added to the gap between the first auxiliary optical component L_1a and the light blocking structure 101 to provide a stronger water leakage prevention function.

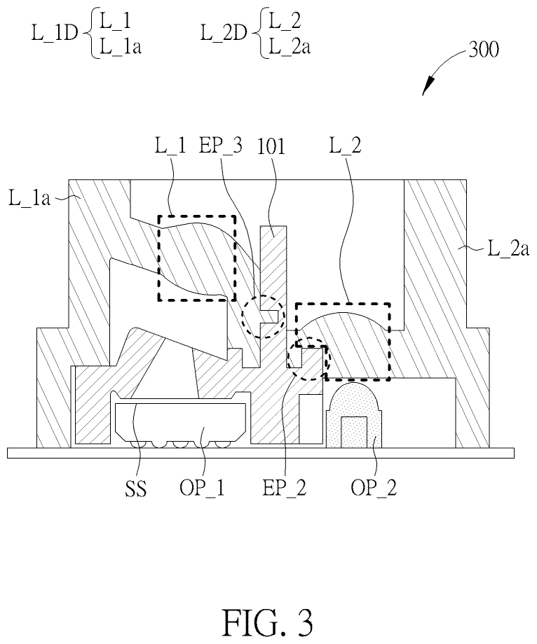

The structure stated in FIG. 1 and FIG. 2 can be applied to another portion of the optical device 100. FIG. 3 is a schematic diagram illustrating an optical device according to another embodiment of the present invention. In the embodiment of FIG. 3, the optical device 300 also comprises a light blocking structure 101, a first optical component OP_1, a first lens device L_1D, a second optical component OP_2, and a second lens device L_2D. The structures of the second optical component OP_2 and the second lens device L_2D are the same as which in FIG. 1 and FIG. 2.

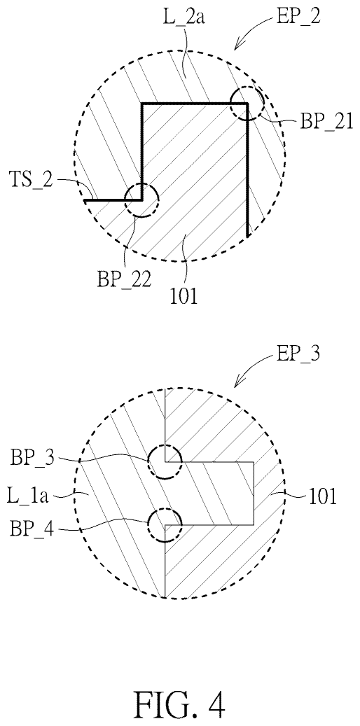

Specifically, in FIG. 3, the second optical component OP_2 is located in a second region next to the light blocking structure 101. The second lens L_2 is located in the second region and above the second optical component OP_2. In one embodiment, the first region and the second region are opposite to each other. FIG. 4 is a schematic diagram illustrating an enlarge drawing of portions EP_2, EP_3 of the embodiment illustrated in FIG. 3. As shown in FIG. 4, a touch region of the second auxiliary optical component L_2a and the light blocking structure 101 forms a second touch surface TS_2, wherein the second touch surface comprises at least one second bending portion, such as bending portions BP_21 and BP_22.

For more detail, in the embodiment of FIG. 4, the light blocking structure 101 comprises a concave portion and the second auxiliary optical component L_2a comprises a protruding portion, wherein the second bending portion BP_22 is formed by the protruding portion bedding into the concave portion. Also, in the embodiment of FIG. 4, the light blocking structure 101 comprises a protruding portion and the second auxiliary optical component L_2a comprises a concave portion, wherein the second bending portion BP_21 is formed by the protruding portion bedding into the concave portion.

In the embodiment of FIG. 4, since the second bending portions BP_21 and BP_22 prolong the path through which water flows, a stronger water leakage prevention function can be provided when water penetrates into the optical device 300. In one embodiment, water proof materials may be added to the gap between the second auxiliary optical component L_2a and the light blocking structure 101 to provide a stronger water leakage prevention function.

FIG. 4 further illustrates an enlarge drawing of the portion EP_3 in FIG. 3. In such case, bending portions BP_3, BP_4 are formed by a protruding portion of the first auxiliary optical component L_1a and a concave portion of the light blocking structure 101. By this way, the path through which water flows can also be prolonged, thus a stronger water leakage prevention function can be provided when water penetrates into the optical device 300.

For more detail, the first optical component OP_1 can sense light from top to bottom, and the protruding direction of the protruding portion of the first auxiliary optical component L_1a is from left to right. Accordingly, the protruding portion is perpendicular with the sensing direction of the first optical component OP_1. In other words, the protruding direction of the first optical component OP_1 is perpendicular with the sensing surface SS of the first optical component OP_1, thus the protruding portion of the first auxiliary optical component L_1a is perpendicular with the sensing direction of the first optical component OP_1. The sensing surface means a surface by which the first optical component OP_1 can receive light.

In another embodiment, the protruding portion of the first auxiliary optical component L_1a in the portion EP_3 is tilted. In such case, the protruding direction is in a direction which is not parallel with the sensing direction. In another embodiment, a protruding portion of the light blocking structure 101 and a concave portion of the first auxiliary optical component L_1a form at least one bending portion. In such case, the protruding direction can also follow the rules for the portion EP_3. Further, following such rule, the protruding portions of the components in the portions EP_1, EP_2 are parallel with the sensing direction of the first optical component OP_1.

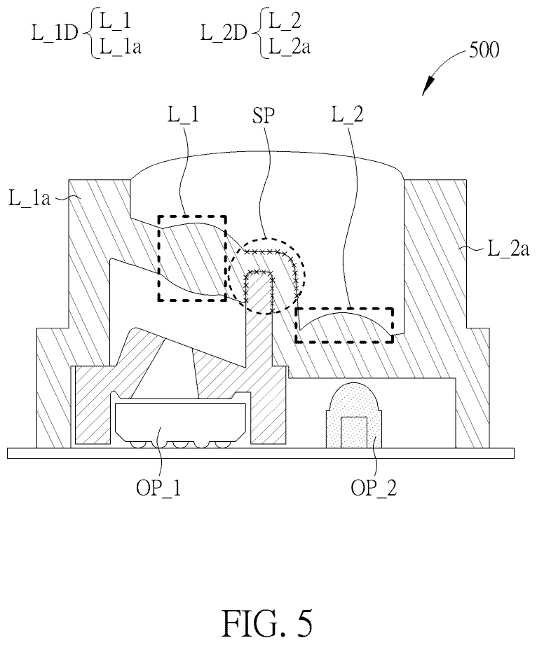

Besides the above-mentioned structures, the present invention further provides other water proof structures. FIG. 5 is a schematic diagram illustrating an optical device 500 according to still another embodiment of the present invention. In the embodiment of FIG. 5, the optical device 500 also comprises a light blocking structure 101, a first optical component OP_1, a first lens device L_1D, a second optical component OP_2, and a second lens device L_2D. In the embodiment of FIG. 5, the firs optical component OP_1 is an image sensor and the second optical component OP_2 is a light source.

In the embodiment of FIG. 5, the first optical component OP_1 is located in a first region next to the light blocking structure; and, and the second optical component OP_2 is located in a second region next to the light blocking structure. In one embodiment, the first region and the second region are opposite to each other. The first lens device L_1D and the second lens device L_2D form a sharing portion SP above the light blocking structure 101. The sharing portion SP has a diffusing structure configured to diffuse light

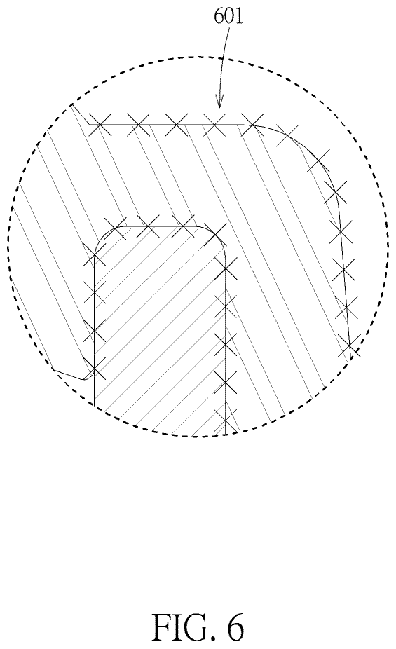

FIG. 6 is a schematic diagram illustrating an enlarge drawing of the sharing portion SP of the embodiment illustrated in FIG. 5. As shown in FIG. 6, the diffusing structure 601 is provided to a surface of the sharing portion SP. In one embodiment, the diffusing structure 601 comprises textures. However, the diffusing structure 601 can be provided inside the sharing portion SP, and can be any other structure which can provide a diffusing function.

In the embodiments of FIG. 5 an FIG. 6, since the first optical component OP_1 and the second optical component OP_2 are covered by the first lens device L_1D and the second lens device L_2D, the water proof function can be enhanced. The first lens device L_1D may comprise the first lens itself (i.e., the first lens L_1) and the first auxiliary optical component L_1a which is connected to the first lens L_1 or formed integrally with the first lens L_1. Similarly, the second lens device L_2D may comprise the second lens itself (i.e., the second lens L_2) and the second auxiliary optical component L_2a which is connected to the second lens L_2 or formed integrally with the second lens L_2. For more detail, the light emitted to the first optical component OP_1 passes through the first lens L_1 but does not pass through the first auxiliary optical component L_1a. Also, the light emitted from the second optical component OP_2 passes through the second lens L_2 but does not pass through the second auxiliary optical component L_2a.

In one embodiment, the first lens device L_1D and the second lens device L_2D are formed in different portions. In such case, water proof material can be provided in the gap formed by the portions to enhance the water proof function, if the gap exists. Further, in another embodiment, the first lens device L_1D and the second lens device L_2D are formed in one, thus can provide better water proof function.

The diffusing structure 601 can diffuse light. As above-mentioned, the second optical component OP_2 may be a light source. In such case, the diffusing structure 601 is configured to diffuse the light emitted from the second optical component OP_2. By this way, the diffusing structure 601 can prevent the second lens device L_2D from receiving the light emitted to the first lens device L_1D.

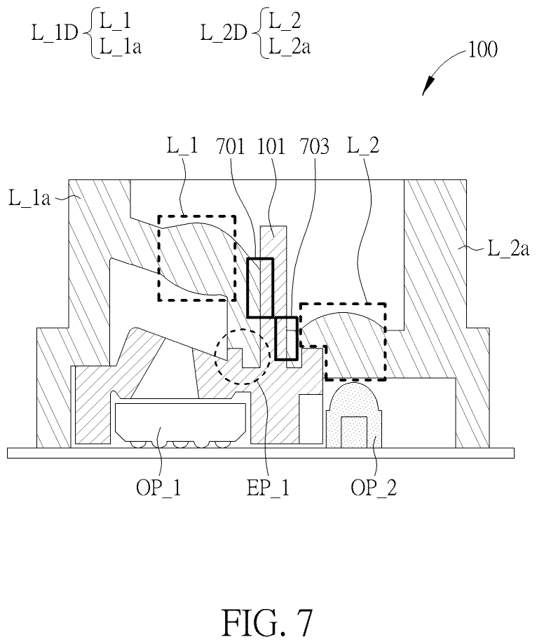

As above-mentioned, water proof materials may be added to the gap between components. FIG. 7 is a schematic diagram illustrating an optical device according to another embodiment of the present invention. As shown in FIG. 7, the water proof materials are added to the gaps in the regions 701 and 703. The gap in the region 701 is a gap between the light blocking structure 101 and the first auxiliary optical component L_1a. Also, the gap in the region 703 is a gap between the light blocking structure 101 and the second auxiliary optical component L_2a. Please note, the water proof materials may be added to the gap between any other components, rather than limited to the example of FIG. 7.

In view of above-mentioned embodiments, the water proof function of the optical device can be improved by simple structures, thus the water leakage issue can be improved without increasing much cost and the assembly complexity.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An optical device, comprising:
a light blocking structure;
a first optical component, located in a first region next to the light blocking structure; and
a first lens device, located in the first region and above the first optical component;
wherein a touch region of the first lens device and the light blocking structure forms a first touch surface, wherein the first touch surface comprises at least one first bending portion.

2. The optical device of claim 1, wherein the light blocking structure comprises a concave portion and the first lens device comprises a protruding portion, wherein the first bending portion is formed by the protruding portion bedding into the concave portion.

3. The optical device of claim 1, wherein the light blocking structure comprises a protruding portion and the first lens device comprises a concave portion, wherein the first bending portion is formed by the protruding portion bedding into the concave portion.

4. The optical device of claim 1, wherein the first optical component is an image sensor.

5. The optical device of claim 1, further comprising:
water proof material, provided to the first touch surface.

6. The optical device of claim 1, further comprising:
a second optical component, located in a second region next to the light blocking structure; and
a second lens device, located in the second region and above the second optical component;
wherein a touch region of the second lens device and the light blocking structure forms a second touch surface, wherein the second touch surface comprises at least one second bending portion.

7. The optical device of claim 6, wherein the light blocking structure comprises a concave portion and the second lens device comprises a protruding portion, wherein the second bending portion is formed by the protruding portion bedding into the concave portion.

8. The optical device of claim 6, wherein the light blocking structure comprises a protruding portion and the second lens device comprises a concave portion, wherein the second bending portion is formed by the protruding portion bedding into the concave portion.

9. The optical device of claim 6,
wherein the first optical component is an image sensor;
wherein the second optical component is a light source;
wherein the light blocking structure is configured to prevent the first optical component from receiving light from the second optical component.

10. The optical device of claim 6, further comprising:
water proof material, provided to the second touch surface.

11. The optical device of claim 6, wherein the first region and the second region are opposite to each other.

12. An optical device, comprising:
a light blocking structure;
a first optical component, located in a first region next to the light blocking structure;
a first lens device, located in the first region and above the first optical component;
a second optical component, located in a second region next to the light blocking structure; and
a second lens device, located in the second region and above the second optical component;
wherein the first lens device and the second lens device form a sharing portion above the light blocking structure;
wherein the sharing portion has diffusing structure configured to diffuse light.

13. The optical device of claim 12, wherein the diffusing structure are textures provided to a surface of the sharing portion.

14. The optical device of claim 12, wherein the first lens device and the second lens device are formed in one.

15. The optical device of claim 12,
wherein the second optical component is a light source;
wherein the diffusing structure is configured to diffuse the light emitted from the first optical component.

16. The optical device of claim 15,
wherein the first optical component is an image sensor;
wherein the light blocking structure is configured to prevent the first optical component from receiving light from the second optical component.

17. The optical device of claim 12, wherein the first region and the second region are opposite to each other.
